(19) United States
(12) Patent Application Publication
(10) Pub. No.: US 2014/0033968 A1
(43) Pub. Date: Feb. 6, 2014

(54) Controlled Doping Device For Single Crystal Semiconductor Material and Related Methods

(71) Applicants: Armando Giannattasio, Lagundo (IT); Stephan Haringer, Ciardes (IT); Roberto Scala, Merano (IT); Valentino Moser, Naturno (IT)

(72) Inventors: Armando Giannattasio, Lagundo (IT); Stephan Haringer, Ciardes (IT); Roberto Scala, Merano (IT); Valentino Moser, Naturno (IT)

(73) Assignee: MEMC Electronic Materials S.p.A, Novara (IT)

(21) Appl. No.: 13/562,445

(22) Filed: Jul. 31, 2012

(51) Int. Cl. C30B 15/04; B21D 51/16

(52) U.S. Cl. 117/19; 117/208; 29/890.09

(57) ABSTRACT

A doping device for a furnace containing a melt includes an upper chamber configured to hold solid dopant particles, a lower chamber, and a feeding tube coupled between the upper chamber and the lower chamber. The feeding tube is configured to supply dopant gas from the upper chamber to the lower chamber, and the lower chamber is configured to diffuse dopant gas over a top surface of the melt.

### FIELD

The field of the invention relates generally to the preparation of semiconductor grade single crystal silicon and, more particularly, to a device for controlled doping of single crystal silicon prepared according to the Czochralski method.

### BACKGROUND

Single crystal silicon, which is the starting material for most processes for the fabrication of semiconductor electronic components, is commonly prepared by the so-called Czochralski (“Cz”) method. In this method, polycrystalline silicon (“polysilicon”) is charged to a crucible and melted, a seed crystal is brought into contact with the molten silicon, and a single crystal is grown by slow extraction.

A certain amount of dopant is added to the melt to achieve a desired resistivity in the silicon crystal. Conventionally, the silicon melt is doped by feeding arsenic onto the melt surface from a feed hopper located a few feet above the silicon melt level. However, this approach is not favorable because arsenic is highly volatile and readily vaporizes when temperatures exceed about 617° C. Thus, when the arsenic contacts the silicon melt surface, which is at a temperature of about 1400° C., it immediately vaporizes and is lost to the gaseous environment in the crystal puller. Vaporization loss of arsenic vapors to the surrounding environment typically results in the generation of oxide particles (i.e., sub-oxides). These particles can fall into the melt and become incorporated into the growing crystal, which is undesirable because the particles can act as heterogeneous nucleation sites and ultimately result in failure of the crystal pulling process (due to a loss of zero-dislocation crystal growth).

Further, in conventional systems, the sublimation of arsenic granules at the melt surface often causes a local temperature reduction of the surrounding silicon melt, which in turn results in the formation of “silicon boats” adjacent the arsenic granules. That is, arsenic sublimation at the melt surface causes localized freezing of the melt surface, in turn causing the formation of solid silicon particles that act as “boats” and resulting in arsenic granules floating on the melt surface. These silicon boats, along with the surface tension of the melt, prevent many of the arsenic granules that do reach the melt surface from sinking into the melt, thus increasing the time during which sublimation to the atmosphere can occur. phenomenon results in a significant loss of arsenic to the gaseous environment and further increases the concentration of contaminant particles in the growth chamber.

An additional problem associated with solid doping is splashing of liquid silicon caused by the impact between the arsenic granules and the melt during the feeding process. These splashes can form silicon drops on parts of the furnace facing the silicon melt, which can fall back into the liquid silicon during the crystal growth and cause the formation of crystal defects.

In view of the foregoing, it can be seen that a need continues to exist for a simple, cost-effective approach to produce low resistivity, doped single crystal silicon by the Czochralski method.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one embodiment, a doping device for a furnace containing a melt is provided. The doping device includes an upper chamber configured to hold solid dopant particles, a lower chamber, and a feeding tube coupled between the upper chamber and the lower chamber. The feeding tube is configured to supply dopant gas from the upper chamber to the lower chamber, and the lower chamber is configured to diffuse dopant gas over a top surface of the melt.

In another embodiment, a method of gas doping a melt in a furnace is described. The method includes providing a gas doping device including an upper chamber configured to hold solid dopant particles, a lower chamber, and a feeding tube coupled between the upper chamber and the lower chamber. The feeding tube is configured to supply dopant gas from the upper chamber to the lower chamber, and the lower chamber is configured to diffuse dopant gas over a top surface of the melt. The method further includes providing solid dopant particles into the upper chamber, lowering the gas doping device into the furnace, and sublimating the solid dopant particles to form the dopant gas. The method further includes directing the dopant gas over the top surface of the melt for absorption therein.

In yet another embodiment, a method of fabricating a doping device for a furnace containing a melt is described. The method includes providing an upper chamber configured to hold solid dopant particles, providing a lower chamber, and providing a feeding tube coupled between the upper chamber and the lower chamber. The feeding tube is configured to supply dopant gas from the upper chamber to the lower chamber, and the lower chamber is configured to diffuse dopant gas over a top surface of the melt.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination

### BRIEF DESCRIPTION OF THE DRAWINGS

FIG. 1 is a cross-sectional view of a furnace containing a silicon melt and a gas doping device; and

FIG. 2 is a cross-sectional view of the gas doping device of FIG. 1.

### DETAILED DESCRIPTION

In accordance with the present disclosure, introducing arsenic into a silicon melt can be controlled in a way that enables a much higher arsenic absorption as compared to methods currently employed in the art. As further described herein, controlled arsenic doping of the silicon melt is achieved by sublimating arsenic granules and introducing the resulting arsenic vapor to a top surface of the melt. As a result, the possibility of process failure, for example due to the formation of particle-related dislocations and/or the loss of crystal structure, is greatly reduced.

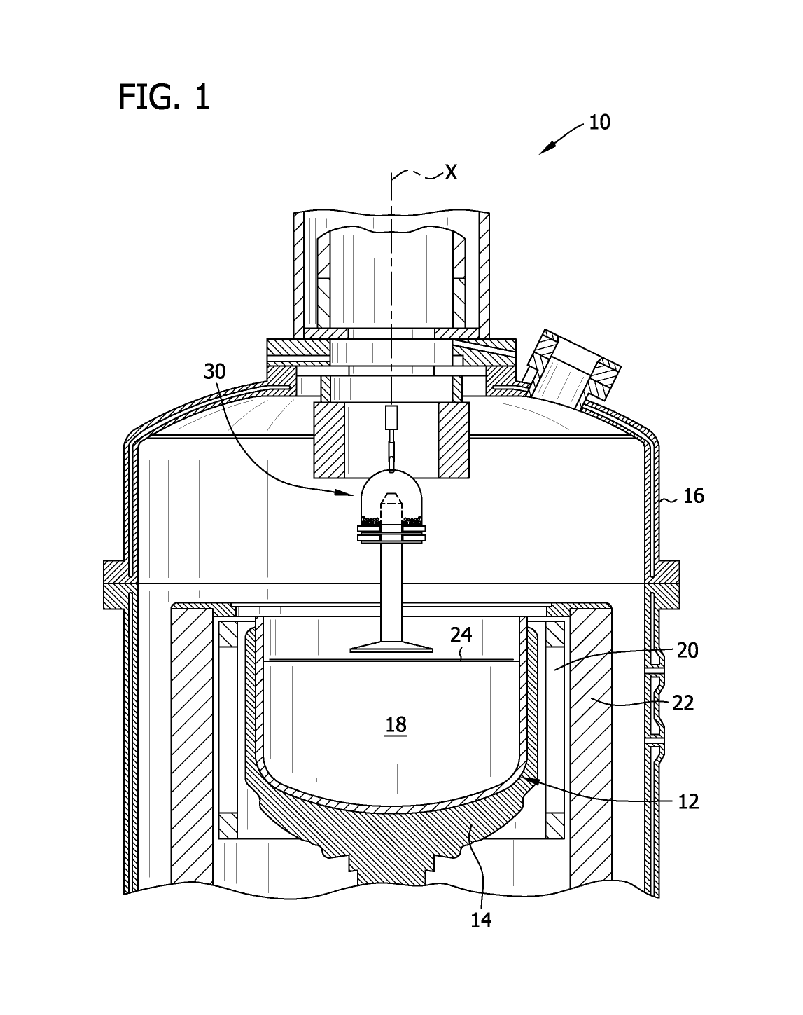

FIG. 1 illustrates a crystal pulling apparatus 10 for producing single crystal ingots by the Czochralski method. The ingots are suitably silicon ingots, though other materials are contemplated in the scope of this disclosure. The crystal pulling apparatus 10 includes a crucible 12 surrounded by a susceptor 14 and contained within a furnace 16. Crucible 12 holds a polycrystalline silicon melt 18 provided by adding solid polycrystalline silicon (not shown) to crucible 12. The solid silicon is melted by heat provided from a heater 20 which surrounds crucible 12. Heater 20 is surrounded by insulation 22. A doping device 30 is positioned within crystal pulling apparatus 10 to introduce dopant to the top surface 24 of silicon melt 18, as described below.

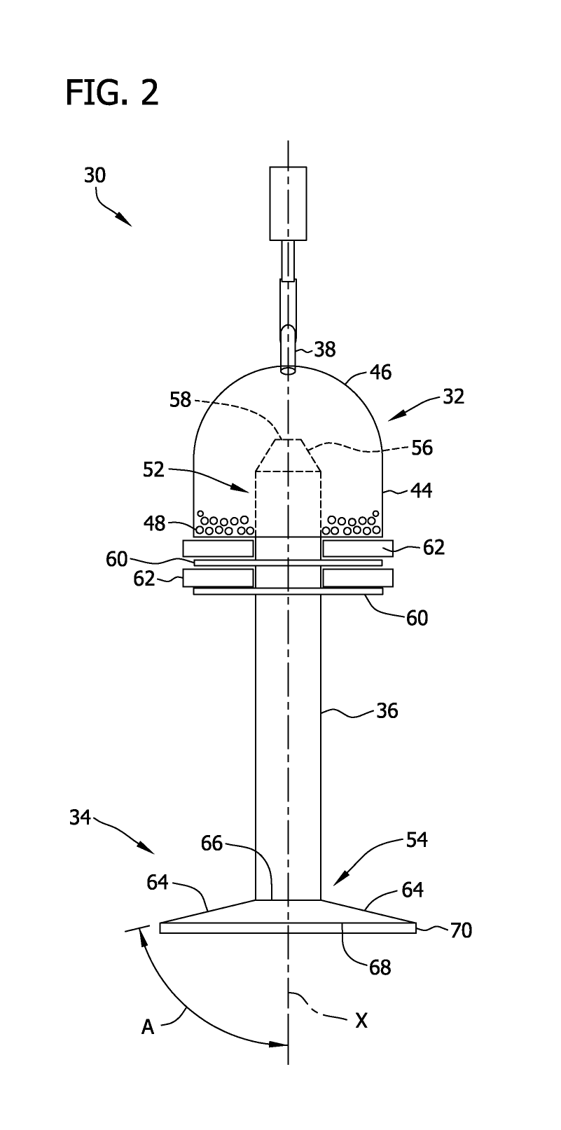

FIG. 2 illustrates an exemplary doping device 30 for use in crystal pulling apparatus 10. Doping device 30 generally includes an upper chamber 32, a lower chamber 34 and a feeding tube 36. A coupling mechanism 38 such as a hook is coupled to upper chamber 32 such that doping device 30 can be hung inside furnace 16 using a pull cable 40 attached to a dummy seed 42. In this way, doping device 30 can be raised and lowered within furnace 16.

Doping device 30 is filled with solid dopant particles 48 and is lowered into furnace 16 where the solid dopant particles 48 are sublimated. The resulting dopant gas is exposed to melt surface 24 to be absorbed into silicon melt 18. In the exemplary embodiment, doping device 30 is fabricated from a single piece of quartz, which facilitates a lightweight and easy to handle device. Alternatively, doping device 30 is formed from any number of parts and any material that enables device 30 to function as described herein.

In the exemplary embodiment, upper chamber 32 includes a generally cylindrical dopant container 44 and a generally hemispherical or domed portion 46. Alternatively, container 44 and portion 46 may have any shape that enables doping device 30 to function as described herein. Upper chamber 32 is configured to receive and hold solid dopant particles 48. Dopant particles 48 may be, for example, arsenic and/or phosphorous granules.

Feeding tube 36 is coupled to upper chamber 32 and includes a first end 52 and a second end 54. First end 52 extends into upper chamber 32 above the fill level of dopant particles 48 such that first end 52 extends through cylindrical dopant container 44 and into a portion of domed portion 46. First end 52 includes a generally frusto-conical end 56 defining an aperture 58 for transfer of dopant. The shape of frusto-conical end 56 is such that aperture 58 has a diameter smaller than the remainder of feeding tube 36 to facilitate preventing solid dopant particles 48 in upper chamber 32 from entering feeding tube 36.

Feeding tube 36 also includes at least one disc 60 coupled to first end 52 beneath upper chamber 32. Disc 60 may be quartz and may be formed integrally with doping device 30. Disc 60 is configured to support one or more insulation layer 62, which is configured to adjust a temperature gradient within upper chamber 32 to achieve a desired evaporation rate of dopant particles 48. Insulation layer 62 is made from any suitable material, for example, silicon, molybdenum and/or graphite felt.

Lower chamber 34 has a generally frusto-conical shape and is coupled to second end 54 of feeding tube 36. Lower chamber 34 includes a wall 64 defining a first end 66 having a smaller diameter than a second end 68. Lower chamber 34 is configured to facilitate even diffusion and circulation of gas dopant near melt surface 24. Walls 64 diverge from first end 66 at an angle A relative to a longitudinal axis X of feeding tube 36. In the exemplary embodiment, angle A is between approximately 65° and 85°. More particularly, angle A is approximately 75° from longitudinal axis X. Angle A formed by walls 64 facilitates prevention of turbulence from down-streaming dopant gas and provides a large surface area of contact between the dopant gas and melt surface 24. A rim 70 projects from second end 68 and is configured to facilitate increased mechanical stability of lower chamber 34 and prevention of dopant gas escaping in a radial direction from lower chamber 34.

During operation, doping device 30 is positioned upside down (as compared to the orientation of FIG. 2) to introduce solid dopant particles 48 into doping device 30. In this position, lower chamber 34 acts as a funnel to receive dopant particles 48, which travel into feeding tube 36, through feeding tube aperture 58, and into upper chamber 32 resting against domed portion 46. When a desired amount of dopant particles 48 have been introduced into upper chamber 32, doping device 30 is rotated 180° such that upper chamber 32 is positioned above lower chamber 34 (as shown in FIG. 2). The light-weight and simple construction of doping device 30 allows an operator to safely rotate the device with one hand and fill the device with the other. Thus, an operator may manipulate and fill doping device 30 without assistance.

During rotation, the hemispherical shape of domed portion 46 provides a smooth surface for dopant particles 48 to slide along, which facilitates preventing dopant particles 48 from falling back through feeding tube 36. The shape of domed portion 46 facilitates reduction of the swinging effect caused by purge gas flow in furnace 16 contacting a curved, rather than a flat, surface. After rotation, doping device 30 is connected to pull cable 40 and lowered into close proximity to melt surface 24 such that rim 70 is between approximately 1-10 mm from melt surface 24. Doping device 30 is configured to be positioned above melt surface 24 and does not contact melt 18, which contact can cause gradual degradation of the device material from thermal shock, silicon solidification around the device wall, and deposition on the device inner surface of silicon monoxide evaporating from the melt.

Once doping device 30 is positioned above the melt surface 24, the temperature inside dopant device 30 increases to the sublimation temperature of dopant particles 48. The temperature distribution inside upper chamber 32 may be at least partially controlled by the addition of one or more insulation layers 62 on discs 60 to adjust the expected evaporation rate for the dopant. As dopant particles 48 begin to reach their sublimation temperature, the particles may begin to react or “jump” within upper chamber 32. Jumping solid dopant particles are prevented from entering feeding tube 36 due to the barrier imposed by the shape of frusto-conical end 56 and reduced size of tube aperture 58, thus preventing solid dopant particles falling into melt 18 and any associated splashing. Additionally, frusto-conical end 56 and aperture 58 are located at a predetermined height above the fill line of solid dopant particles 48, at which height jumping dopant particles cannot overcome and enter into feeding tube 36.

As solid dopant particles 48 sublimate, the resulting dopant gas flows through tube aperture 58 and feeding tube 36 to lower chamber 34. However, a portion of dopant gas may condense against the relatively cooler walls of domed portion 46 and may subsequently fall therefrom. However, the shape of frusto-conical end 56 and reduced size aperture 58 facilitate preventing the falling condensed dopant from entering feeding tube 36 and falling into melt 18. Additionally, one or more insulation layer 62 may be used to adjust the temperature profile of upper chamber 32 such that the inside walls of domed portion 46 have a higher temperature than the sublimation temperature, thus preventing condensation.

Dopant gas flowing to lower chamber 34 is diffused by the diverging walls 64 and is circulated over the melt surface 24. The increased diameter of lower chamber second end 68 provides a large contact area over surface 24 for gas dopant. Rim 16 prevents dopant gas from dispersing radially, and the dopant gas is absorbed by melt 18. Once dopant particles 48 have sublimated and/or a predetermined amount of time has elapsed, dopant device 30 is raised by cable 40 and removed from furnace 16. The doping process may then be repeated or the dopant device 30 may be stored for later use.

As described above, dopant device 30 and associated methods provide an improvement over known doping systems and techniques. As compared to some known systems, dopant device 30 avoids the problems associated with the direct doping method, namely absorption efficiency, floating boats, and splashing caused by dopant granules. In particular, absorption efficiency is increased with device 30 because dopant vapor is not lost to the surrounding environment, and the dopant is sublimated and then introduced to the melt surface with device 30, which prevents the occurrence of floating boats and splashing from solid dopant dropped onto the melt surface. Further, the single component, high-purity quartz design of dopant device 30 provides a single path for dopant vapor to flow to the melt surface, preventing efficiency loss associated with multiple vapor flow paths (e.g. vapor escaping through holes or slits in interfaces of multi-component devices).

Moreover, dopant device 30 has a simple geometry and construction, and is easily handled, which allows for use by a single operator. Dopant device 30 is also designed to avoid the need for full or partial submersion of the device into the melt, thus preventing device degradation.

While the invention has been described in terms of various specific embodiments, it will be recognized that the invention can be practiced with modification within the spirit and scope of the claims.

When introducing elements of the present disclosure or the embodiments thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A doping device for a furnace containing a melt, the device comprising:
an upper chamber configured to hold solid dopant particles;
a lower chamber; and
a feeding tube coupled between the upper chamber and the lower chamber, the feeding tube configured to supply dopant gas from the upper chamber to the lower chamber,
wherein the lower chamber is configured to diffuse dopant gas over a top surface of the melt.

2. The doping device of claim 1, wherein an entrance of the feeding tube extends into the upper chamber, the feeding tube entrance positioned above a fill level of solid dopant particles.

3. The doping device of claim 2, wherein the feeding tube entrance comprises a generally frusto-conical taper configured to prevent reacting solid dopant particles from entering the feeding tube.

4. The doping device of claim 1, wherein at least one quartz member is coupled to the feeding tube below the upper chamber, the quartz member configured to hold a layer of insulation.

5. The doping device of claim 4, further comprising at least one layer of insulation positioned on the at least one quartz member, the at least one layer of insulation configured to adjust the temperature profile of the device.

6. The doping device of claim 1, wherein the gas doping device is a single integral piece of quartz.

7. The doping device of claim 1, wherein the lower chamber is generally frusto-conical and includes a first diameter end and second diameter end larger than the first diameter end, the first diameter end coupled to the feeding tube to receive the dopant gas and the second diameter end configured to evenly diffuse the dopant gas over the top surface of the melt.

8. The doping device of claim 7, further comprising a rim projecting from the second diameter end of the lower chamber, the rim configured to direct dopant gas towards the melt and prevent dopant gas from dispersing radially.

9. The doping device of claim 7, wherein the frusto-conical lower chamber further includes a wall extending between the first and second diameter ends, the wall being angled between approximately 65 degrees and 85 degrees relative to a longitudinal axis of the feeding tube.

10. The doping device of claim 9, wherein the wall is angled at approximately 75 degrees relative to the longitudinal axis of the feeding tube.

11. The doping device of claim 1, wherein the upper chamber includes a domed upper wall to inhibit release of dopant.

12. The doping device of claim 1, wherein the upper chamber comprises a generally cylindrical lower portion and a generally hemispherical upper portion.

13. The doping device of claim 1, wherein the solid dopant particles are at least one of arsenic and phosphorous.

14. The doping device of claim 1, further comprising a hook coupled to the upper chamber, the hook configured to releasably couple to a cable to lower the gas doping device into the furnace.

15. A method of gas doping a melt in a furnace, the method comprising:
providing a gas doping device comprising:
an upper chamber configured to hold solid dopant particles;
a lower chamber; and
a feeding tube coupled between the upper chamber and the lower chamber, the feeding tube configured to supply dopant gas from the upper chamber to the lower chamber, wherein the lower chamber is configured to diffuse dopant gas over a top surface of the melt;
providing solid dopant particles into the upper chamber;
lowering the gas doping device into the furnace;
sublimating the solid dopant particles to form the dopant gas; and
directing the dopant gas over the top surface of the melt for absorption therein.

16. The method of claim 15, wherein providing solid dopant particles into the upper chamber comprises:
positioning the upper chamber below the lower chamber;
introducing solid dopant particles into an opening of the lower chamber such that the solid dopant particles travel through the feeding tube and into the upper chamber; and
rotating the gas doping apparatus approximately 180 degrees such that the upper chamber is positioned above the lower chamber.

17. The method of claim 15, wherein lowering the gas doping device into the furnace comprises lowering the gas doping device into the furnace such that the lower chamber is positioned above the top surface of the melt.

18. The method of claim 15, further comprising positioning at least one insulating layer between the upper chamber and the lower chamber to adjust the temperature profile of the gas doping device.

19. A method of fabricating a doping device for a furnace containing a melt, the method comprising:
providing an upper chamber configured to hold solid dopant particles;
providing a lower chamber;
providing a feeding tube coupled between the upper chamber and the lower chamber, the feeding tube configured to supply dopant gas from the upper chamber to the lower chamber, wherein the lower chamber is configured to diffuse dopant gas over a top surface of the melt.

20. The method of claim 19, further comprising fabricating the gas doping device from a single integral piece of material.
